(19) United States
(12) Patent Application Publication
(10) Pub. No.: US 2025/0174498 A1
(43) Pub. Date: May 29, 2025

(54) Die-Level Parametric Prediction Boosting Method and Die-Level Parametric Prediction Boosting System for Improving Prediction Accuracy by Incorporating a Wafer Map Distribution

(71) Applicant: MEDIATEK INC., Hsinchu City (TW)

(72) Inventors: Chin-Wei Lin, Hsinchu City (TW); Chi-Ming Lee, Hsinchu City (TW); Po-Chao Tsao, Hsinchu City (TW); Tsung-Te Chen, Hsinchu City (TW); Khim Jun Koh, Hsinchu City (TW); Yu-Lin Yang, Hsinchu City (TW); Cheng-Tien Wan, Hsinchu City (TW); Yi-Ju Ting, Hsinchu City (TW); Tung-Hsing Lee, Hsinchu City (TW)

(73) Assignee: MEDIATEK INC., Hsinchu City (TW)

(21) Appl. No.: 18/948,441

(22) Filed: Nov. 14, 2024

Related U.S. Application Data
(60) Provisional application No. 63/603,677, filed on Nov. 29, 2023.

(51) Int. Cl. H01L 21/66; H01L 21/67

(52) U.S. Cl. CPC H01L 22/14; H01L 21/67259; H01L 22/12; H01L 22/34

(57) ABSTRACT

A die-level parametric prediction boosting method includes acquiring mass production data of a plurality of dies, identifying a comprehensive indicator of each die according to the mass production data, generating a wafer map distribution of the plurality of dies according to a plurality of comprehensive indicators, partitioning the plurality of dies into at least two die clustering groups, and inputting a plurality of electrical parametric features of each die clustering group to a training model for generating predicted data of each die clustering group.

### CROSS REFERENCE TO RELATED APPLICATIONS

This application claims the benefit of U.S. Provisional Application No. 63/603,677, filed on Nov. 29, 2023. The content of the application is incorporated herein by reference.

### BACKGROUND

With the rapid advancement of technologies, various chips and integrated circuits (ICs) are adopted in our daily life. Therefore, high quality and low operational risk ICs are required for various electronic applications. In a silicon testing flow, to provide high quality and low operational risk ICs, outlier ICs are identified and labeled by analyzing measured testing data.

However, in a conventional outlier IC identification method, some outlier ICs can be identified according to their measured testing data. It should be understood that different ICs have different electrical parametric features. Therefore, since the feature distribution of the ICs is non-uniform, it is hard to accurately predict outlier ICs according to predicted data.

Therefore, developing a parametric prediction system capable of boosting prediction accuracy is an important design issue.

### SUMMARY

In an embodiment of the present invention, a die-level parametric prediction boosting method is disclosed. The die-level parametric prediction boosting method comprises acquiring mass production data of a plurality of dies, identifying a comprehensive indicator of each die according to the mass production data, generating a wafer map distribution of the plurality of dies according to a plurality of comprehensive indicators, partitioning the plurality of dies into at least two die clustering groups, and inputting a plurality of electrical parametric features of each die clustering group to a training model for generating predicted data of each die clustering group.

In another embodiment of the present invention, a die-level parametric prediction boosting system is disclosed. The die-level parametric prediction boosting system comprises a mass production data source, an artificial intelligence (AI) clustering unit coupled to the mass production data source, and a training model coupled to the AI clustering unit. The AI clustering unit acquires mass production data of a plurality of dies from the mass production data source. The AI clustering unit identifies a comprehensive indicator of each die according to the mass production data. The AI clustering unit generates a wafer map distribution of the plurality of dies according to a plurality of comprehensive indicators. The AI clustering unit partitions the plurality of dies into at least two die clustering groups. A plurality of electrical parametric features of each die clustering group are inputted to the training model for generating predicted data of each die clustering group.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram of a die-level parametric prediction boosting system according to an embodiment of the present invention.

FIG. 2 is an illustration of partitioning the plurality of dies into N die clustering groups from a wafer map distribution of the die-level parametric prediction boosting system in FIG. 1.

FIG. 3 is a flow chart of performing a die-level parametric prediction boosting method by the die-level parametric prediction boosting system in FIG. 1.

### DETAILED DESCRIPTION

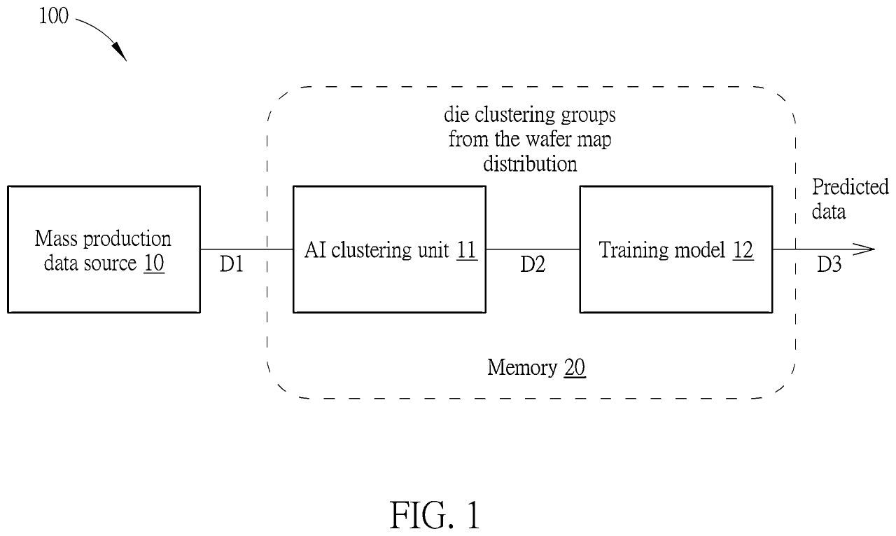

FIG. 1 is a block diagram of a die-level parametric prediction boosting system 100 according to an embodiment of the present invention. The die-level parametric prediction boosting system 100 includes a mass production data source 10, an artificial intelligence (AI) clustering unit 11, and a training model 12. The mass production data source 10 can be at least one stage node of a wafer testing line. For example, the mass production data source 10 can be a chip probe (CP) stage node or a final test (FT) stage node. The CP stage node or the FT stage node can provide the mass production data. In another embodiment, the mass production data source 10 can be the CP stage node and the FT stage node of the wafer testing line. The CP stage node and the FT stage node can jointly provide the mass production data. The AI clustering unit 11 is coupled to the mass production data source 10. The training model 12 is coupled to the AI clustering unit 11. The training model 12 and the AI clustering unit 11 can be neural network architecture. Program and data of the training model 12 and the AI clustering unit 11 can be saved in a memory 20. In the die-level parametric c prediction boosting system 100, the AI clustering unit 10 can acquire mass production data of a plurality of dies from the mass production data source 10. The AI clustering unit 11 can identify a comprehensive indicator of each die according to the mass production data. Then, the AI clustering unit 11 generates a wafer map distribution of the plurality of dies according to a plurality of comprehensive indicators. The AI clustering unit 11 partitions the plurality of dies into at least two die clustering groups. The plurality of electrical parametric features of each die clustering group are inputted to the training model 12 for generating predicted data of each die clustering group. Briefly, the die-level parametric prediction boosting system 100 can improve prediction accuracy by incorporating a wafer map distribution. Details of partitioning the plurality of dies according to the wafer map distribution are illustrated below.

In FIG. 1, the mass production data D1 of the mass production data source 10 (i.e., at least one stage node of the wafer testing line) can be received by the AI clustering unit 11. In an embodiment, the AI clustering unit 11 acquires N electrical parametric features of each die according to the mass production data D1. N is a positive integer. The N electrical parametric features can include senor data or detector data of each die. N is a positive integer. Then, the AI clustering unit 11 can determine the “comprehensive indicator” of each die according to the N electrical parametric features. For example, the N electrical parametric features of each die can be linearly or non-linearly combined for generating the comprehensive indicator. Then, the AI clustering unit 11 can acquire a wafer map distribution according to the plurality of comprehensive indicators. After the wafer map distribution is acquired, the AI clustering unit 11 can determine a boundary of each die clustering group on the wafer map distribution of the plurality of dies according to the plurality of comprehensive indicators. Here, electrical parametric features of each die clustering group with a boundary range are highly correlated. Each die clustering group can include M dies. M is a positive integer.

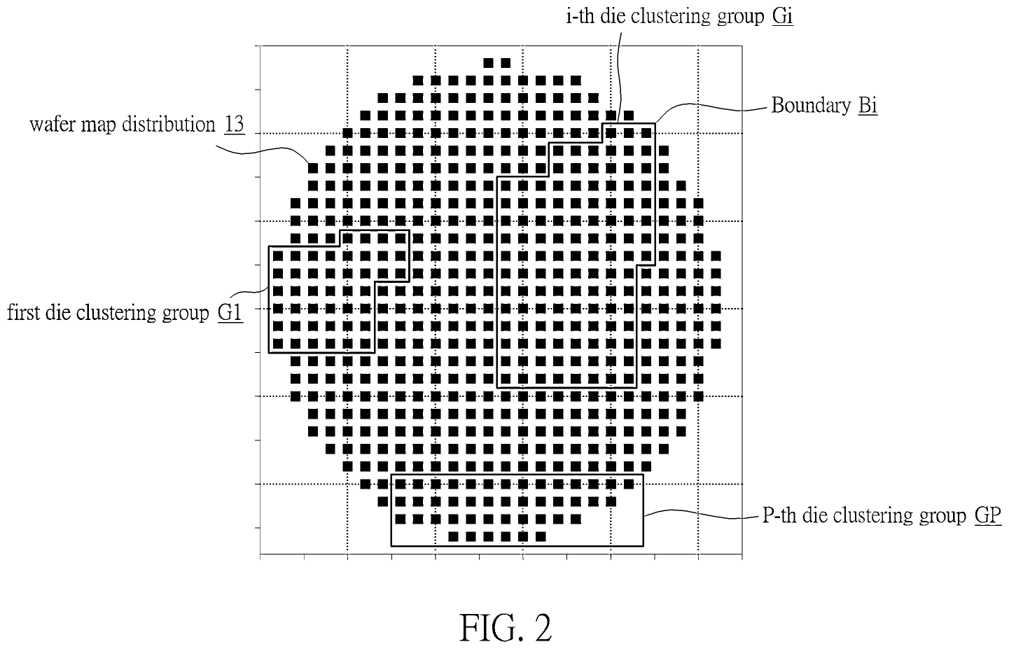

FIG. 2 is an illustration of partitioning the plurality of dies into P die clustering groups from the wafer map distribution 13 of the die-level parametric prediction boosting system 100. As previously mentioned, the plurality of dies of the wafer map distribution can be partitioned into P die clustering groups. For example, a first die clustering group G1 to a P-th die clustering group GP can be introduced in FIG. 2. P can be a positive integer. Further, each die clustering group can include M dies. Each die clustering group is determined according to the boundary. For example, an i-th die clustering group Gi can be determined according to an i-th boundary. After P die clustering groups of the wafer map distribution 13 are determined, the N electrical parametric features of each die can be inputted to the training model 12. For example, data D2 (shown in FIG. 1) of the N electrical parametric features of the i-th die clustering group Gi can be expressed as Table T1.

TABLE T1

| | |
|---|---|
| index n = 1 | electrical parametric feature-1 (i) |
| index n = 2 | electrical parametric feature-2 (i) |
| . . . | . . . |
| index n = N | electrical parametric feature-N (i) |

As previously mentioned, after the P die clustering groups are generated, since all dies within each die clustering group are highly correlated, the training model 12 can infer the predicted data D3 (shown in FIG. 1) with high prediction accuracy. In the embodiment, the plurality of electrical parametric features of each die can include a chip speed or a chip power leakage measured by a senor or a detector of each die. The predicted data D3 of each die clustering group can include an ON/OFF current, a threshold voltage, or channel information of metal-oxide-semiconductor field-effect transistors (MOSFETs). Any technology or hardware modification falls into the scope of the present invention.

In the parametric prediction boosting system 100, the training model 12 should be fully trained before the training model 12 infers the predicted data D3. In an embodiment, die training data can be acquired from the CP stage node or the FT stage node. Then, after the die training data is acquired, the training model 12 can be established according to the die training data. Then, die validation data can be used for determining if the training model 12 is fully trained. When the training model 12 is not fully trained, the training model 12 is re-trained or continuously trained according to the die training data. When the training model 12 is fully trained, the training model 12 is outputted as a finalized training model for generating the predicted data D3. The training model 12 can be implemented by using any neural network architecture, such as a convolutional neural network (CNN) or a recurrent neural network (RNN). Table T2 shows a prediction improvement of the parametric prediction boosting system 100.

TABLE T2

| | | | | Prediction |
|---|---|---|---|---|
| number of | die | die | predicted | accuracy |
| electrical | training | validation | data | improvement |
| parametric | data | data | (threshold | (R-squared |
| features | (Wafer) | (Wafer) | voltage) | correlation) |
| N = 436 | 700 | 175 | Vth | from 0.307 to |
| | Wafers | Wafers | | 0.323 |
| | | | | from 0.288 to |
| | | | | 0.299 |
| | | | | from 0.301 to |
| | | | | 0.306 |

As shown in Table T2, the training model 12 can be trained according to 436 electrical parametric features of 700 wafers. The training model 12 can be fully trained as the finalized training model by using the die validation data of 175 wafers. As previously mentioned, since all dies within each die clustering group are highly correlated, the training model 12 can infer the predicted data with high prediction accuracy. In Table T2, the prediction accuracy is scaled as R-squared correlations. In the embodiment, the R-squared correlations are increased since the die-level parametric prediction boosting system 100 incorporates the wafer map distribution.

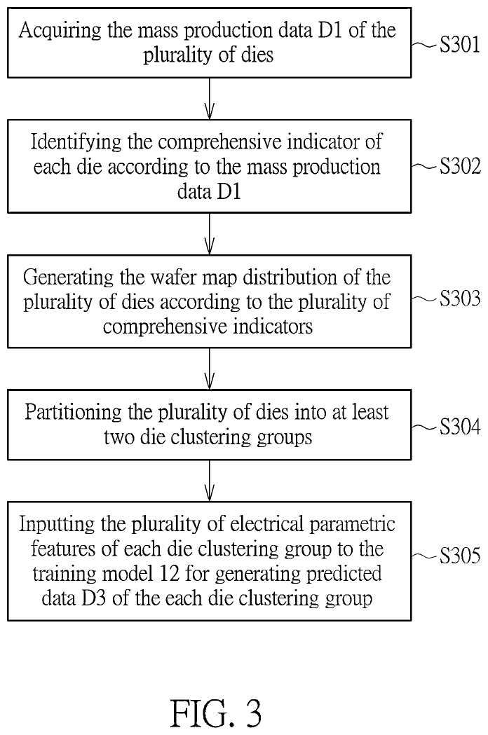

FIG. 3 is a flow chart of performing a die-level parametric prediction boosting method by the die-level parametric prediction boosting system 100. The die-level parametric prediction boosting method includes step S301 to step S305. Any technology or hardware modification falls into the scope of the present invention. Step S301 to step S305 are illustrated below.
step S301: acquiring the mass production data D1 of the plurality of dies;
step S302: identifying the comprehensive indicator of each die according to the mass production data D1;
step S303: generating the wafer map distribution of the plurality of dies according to the plurality of comprehensive indicators;
step S304: partitioning the plurality of dies into at least two die clustering groups;
step S305: inputting the plurality of electrical parametric features of each die clustering group to the training model 12 for generating predicted data D3 of the each die clustering group.

Details of step S301 to step S305 are previously illustrated. Thus, they are omitted here. In the die-level parametric prediction boosting system 100, instead of directly predicting data of the plurality of dies according to electrical parametric features, the AI clustering unit 11 and the training model 12 can be introduced for incorporating the wafer map distribution with the electrical parametric features. Therefore, die information collected by the training model 12 can be increased. The prediction accuracy can be boosted.

To sum up, the present invention discloses a die-level parametric prediction boosting method and a die-level parametric prediction boosting system. The die-level parametric prediction boosting system uses two stages for predicting data of the plurality of dies. In a first stage, the plurality of dies are partitioned into P die clustering groups according to the wafer map distribution. In a second stage, N electrical parametric features of each die clustering group can be used for predicting data by the training model. All dies within each die clustering group are highly correlated. As a result, the die-level parametric prediction boosting system can infer the predicted data with high prediction accuracy.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A die-level parametric prediction boosting method comprising:
acquiring mass production data of a plurality of dies;
identifying a comprehensive indicator of each die according to the mass production data;
generating a wafer map distribution of the plurality of dies according to a plurality of comprehensive indicators;
partitioning the plurality of dies into at least two die clustering groups; and
inputting a plurality of electrical parametric features of each die clustering group to a training model for generating predicted data of the each die clustering group.

2. The method in claim 1, wherein acquiring the mass production data of the plurality of dies, is acquiring the mass production data of the plurality of dies from a chip probe (CP) stage node and/or a final test (FT) stage node.

3. The method in claim 1, further comprising:
acquiring N electrical parametric features of the each die according to the mass production data; and
determining the comprehensive indicator of the each die according to the N electrical parametric features;
wherein the N electrical parametric features comprise senor data or detector data of the each die, and N is a positive integer.

4. The method in claim 1, wherein the each die clustering group comprises at least one die, and electrical parametric features of the each die clustering group are highly correlated.

5. The method in claim 1, further comprising:
determining a boundary of the each die clustering group on the wafer map distribution of the plurality of dies according to the plurality of comprehensive indicators.

6. The method in claim 1, wherein the plurality of electrical parametric features of the each die comprise a chip speed or a chip power leakage measured by a senor or a detector of the each die.

7. The method in claim 1, wherein the predicted data of the each die clustering group comprises an ON/OFF current, a threshold voltage, or channel information of metal-oxide-semiconductor field-effect transistors (MOSFETs).

8. The method in claim 1, further comprising:
acquiring die training data;
establishing the training model according to the die training data; and
using die validation data for determining if the training model is completely trained.

9. The method in claim 8, further comprising:
when the training model is not fully trained, re-training the training model according to the die training data.

10. The method in claim 8, further comprising:
when the training model is fully trained, outputting the training model as a finalized training model for generating the predicted data.

11. A die-level parametric prediction boosting system comprising:
a mass production data source;
an artificial intelligence (AI) clustering unit coupled to the mass production data source; and
a training model coupled to the AI clustering unit;
wherein the AI clustering unit acquires mass production data of a plurality of dies from the mass production data source, the AI clustering unit identifies a comprehensive indicator of each die according to the mass production data, the AI clustering unit generates a wafer map distribution of the plurality of dies according to a plurality of comprehensive indicators, the AI clustering unit partitions the plurality of dies into at least two die clustering groups, a plurality of electrical parametric features of each die clustering group are inputted to the training model for generating predicted data of the each die clustering group.

12. The system in claim 11, wherein the mass production data source comprises a chip probe (CP) stage node and/or a final test (FT) stage node.

13. The system in claim 11, wherein the AI clustering unit acquires N electrical parametric features of the each die according to the mass production data, the AI clustering unit determines the comprehensive indicator of the each die according to the N electrical parametric features, the N electrical parametric features comprise senor data or detector data of the each die, and N is a positive integer.

14. The system in claim 11, wherein the each die clustering group comprises at least one die, and electrical parametric features of the each die clustering group are highly correlated.

15. The system in claim 11, wherein the AI clustering unit determines a boundary of the each die clustering group on the wafer map distribution of the plurality of dies according to the plurality of comprehensive indicators.

16. The system in claim 11, wherein the plurality of electrical parametric features of the each die comprise a chip speed or a chip power leakage measured by a senor or a detector of the each die.

17. The system in claim 11, wherein the predicted data of the each die clustering group comprises an ON/OFF current, a threshold voltage, or channel information of metal-oxide-semiconductor field-effect transistors (MOSFETS).

18. The system in claim 11, wherein after die training data is acquired, the training model is established according to the die training data, and die validation data is used for determining if the training model is fully trained.

19. The system in claim 18, wherein when the training model is not fully trained, the training model is re-trained according to the die training data.

20. The system in claim 18, wherein when the training model is fully trained, the training model is outputted as a finalized training model for generating the predicted data.
